(19) United States
(12) Patent Application Publication
(10) Pub. No.: US 2008/0074001 A1
(43) Pub. Date: Mar. 27, 2008

(54) Ion conducting actuator apparatus and optical diaphragm apparatus

(75) Inventor: Takayuki Ide, Tokyo (JP)

Correspondence Address: SCULLY SCOTT MURPHY & PRESSER, PC, 400 GARDEN CITY PLAZA, SUITE 300, GARDEN CITY, NY, 11530, US

(73) Assignee: Olympus Corporation, Tokyo (JP)

(21) Appl. No.: 11/901,977

(22) Filed: Sep. 20, 2007

(30) Foreign Application Priority Data
Sep. 26, 2006 (JP) JP 2006-260005

(51) Int. Cl. H01L 41/08; H01L 41/00

(52) U.S. Cl. 310/330

(57) ABSTRACT

An ion conducting actuator includes facing electrodes on a surface of a base material which is made of an ion exchange resin. An output from a drive voltage supply is applied to the facing electrodes via an electrode pad. Here, when a negative voltage is applied to the electrode on a left side and a positive voltage is applied to the electrode on a right side, an electric field is generated due to the voltage applied. Due to the electric field, negative ions and/or polar molecules in the base material move to a negative pole side, and the negative pole side is swollen as compared to a positive pole side, and a front end of the base material is deformed to a right side in the diagram. On the other hand, when a negative voltage is applied to an electrode on a right side, and a positive voltage is applied to an electrode on a left side, there is a reverse effect of the effect mentioned above, and the front end of the base material is deformed to a left side in the diagram. The ion conducting actuator is driven by using these characteristics.

### CROSS-REFERENCE TO RELATED APPLICATION

The present application is based upon and claims the benefit of priority from the prior Japanese Patent Application No. 2006-260005 filed on Sep. 26, 2006; the entire contents of which are incorporated herein by reference.

### BACKGROUND OF THE INVENTION

1. Field of the Invention

The present invention relates to an ion conducting actuator apparatus, and an optical diaphragm apparatus in which the ion conducting actuator apparatus is used.

2. Description of the Related Art

In recent years, in fields such as medical equipments, industrial robots, and micro machines, research and development of actuators in which various principles of operation are applied have been carried out. Among these, an ion conducting actuator in which, an electrode is formed on a surface of an ion exchange resin in a form in which polar molecules such as an ion fluid are included, and is deformed by bending by applying a voltage has been called as an artificial muscle for its flexible driving mode. The artificial muscle is expected to have applications in various fields from now onward.

For example, in Japanese Patent Application Laid-open Publication No. 2004-282992, examples of structures of various ion conducting actuators have been disclosed. Moreover, in Japanese Patent Application Laid-open Publication No. 2004-282992, a number of cases have been proposed as applications which use the ion conducting actuator.

However, in the ion conducting actuator, from a point of view of durability and response, it is necessary to pay attention to a driving method and a mechanism of an application.

### SUMMARY OF THE INVENTION

The present invention is made in view of the abovementioned circumstances, and an object of the present invention is to provide an ion conducting actuator apparatus which is capable of realizing more suitable operation, in which a durability and a response are taken into consideration. Moreover, an object of the present invention is to provide an optical diaphragm apparatus in which this ion conducting actuator is used.

For solving the abovementioned issues, and achieving the object, there is provided an ion conducting actuator apparatus according to the present invention which includes

an ion conducting actuator which includes a base material substrate made of an ion conducting high-polymer material, and facing electrodes which are formed on a surface of the base material, and

a driven section which assumes a first effective state and a second effective state according to a deformation of the ion conducting actuator, when a voltage is applied to the ion conducting actuator, and

during a transition period in which, the driven section undergoes a transition between the first effective state and the second effective state, a drive voltage which is necessary for displacing the driven section is applied.

According to a preferable aspect of the present invention, it is desirable that the voltage is not applied to the ion conducting actuator during a period other than the transition period.

Moreover, according to a preferable aspect of the present invention, it is desirable that a preparation voltage which is necessary for the driven section to start displacement is applied to the ion conducting actuator during a period other than the transition period.

Furthermore, according to a preferable aspect of the present invention, it is desirable that during the transition period, after the ion conducting actuator is deformed to a predetermined shape, the voltage is applied continuously till the second effective state.

According to a preferable aspect of the present invention, it is desirable that the driven section includes a connecting member which connects the driven section and the ion conducting actuator, and the driven section undergoes a transition mutually between the first effective state and the second effective state via the connecting member.

Moreover, according to a preferable aspect of the present invention, the connecting member is joined to the ion conducting actuator, and includes a first contact section and a second contact section, and

due to a contact section provided on the driven section, making a contact with the first contact section, when the driven section undergoes a transition to the first effective state, and

due to the contact section and the second contact section making a contact when the driven section undergoes a transition to the second effective state,

the driven section is made to undergo a transition mutually between the first effective state and the second effective state.

Furthermore, according to a preferable aspect of the present invention, it is desirable that the connecting member is joined to the driven section, and includes a first contact section and a second contact section, and also includes a contact section which is joined to or provided on the ion conducting actuator, and

due to the contact section and the first contact section making a contact, when the driven section undergoes a transition to the first effective state, and

due to the contact section and the second contact section making a contact, when the driven section undergoes a transition to the second effective state,

the driven section is made to undergo a transition mutually between the first effective state and the second effective state.

According to a preferable aspect of the present invention, it is desirable that the ion conducting actuator apparatus further includes a holding means which maintains a state of the driven section, and

when the driven section has undergone a transition to the first effective state or the second effective state according to the deformation of the ion conducting actuator, the holding means maintains the state of the driven section.

According to a second aspect of the present invention, there is provided an optical diaphragm apparatus including
an ion conducting actuator provided on a substrate which includes a substrate having an aperture, a blade having an aperture smaller than the aperture formed in the substrate, a base material which is formed of an ion conducting high-polymer material, and facing electrodes which are formed on a surface of the base material, and

a voltage is applied to the ion conducting actuator, and a blade having an aperture is driven according to a deformation of the ion conducting actuator, and made to undergo a transition to a first effective state of overlapping with the aperture formed in the substrate, and a second effective state of being retracted from the aperture formed in the substrate, thereby changing an aperture diameter, and

during a transition period in which a transition between the first effective state and the second effective state occurs, a drive voltage which is necessary for driving the ion conducting actuator is applied.

According to a preferable aspect of the present invention, it is desirable that the optical diaphragm apparatus further includes

a holding means which maintains a state of the blade having the aperture, and

when the blade having the aperture has undergone transition to the first effective state or the second effective state according to the deformation of the ion conducting actuator, the holding means maintains the state of the driven section.

### BRIEF DESCRIPTION OF THE DRAWINGS

FIG. 1 is a diagram in which, electrical connections of a drive voltage source and an ion conducting actuator according to a first embodiment of the present invention, are shown schematically;

FIG. 2A and FIG. 2B are diagrams in which a deformed state, when a positive and a negative voltage are applied to facing electrodes according to the first embodiment, is shown;

FIG. 3 is a diagram in which a structure of a diaphragm apparatus (first effective state) which is made of a diaphragm mechanism and the ion conducting actuator according to the first embodiment is shown;

FIG. 4 is a diagram in which, a diaphragm blade according to the first embodiment is shown in an enlarged form;

FIG. 5 is a diagram in which, a state of being deformed (first transition state) such that a chord length is extended upon applying a voltage to the ion conducting actuator according to the first embodiment is shown;

FIG. 6 is a diagram in which, a state of being open (second effective state) in which the voltage is not applied to the ion conducting actuator according to the first embodiment is shown;

FIG. 7 is a diagram in which a state of being deformed (second transition state) such that the chord length is shortened upon applying the voltage to the ion conducting actuator according to the first embodiment is shown;

FIG. 8A and FIG. 8B are diagrams in which a relationship (the most basic usage pattern) of a position of a diaphragm blade, an effective state and a transition state, and a voltage applied to the ion conducting actuator in the first embodiment is described;

FIG. 9A and FIG. 9B are diagrams in which a usage pattern in a case in which, after the diaphragm blade has reached an partially open position or an open position, a delay time is provided for settling that state assuredly, in the first embodiment, is described;

FIG. 10A and FIG. 10B are diagrams in which a usage pattern in a case in which, at the time of driving the diaphragm blade, for eliminating a delay during a time while being released from a latching mechanism, a preparation time for applying a preparation voltage to the ion conducting actuator in advance is provided;

FIG. 11 is a diagram in which a second embodiment of the present invention is described;

FIG. 12 is a diagram in which a third embodiment of the present invention is described; and

FIG. 13 is a diagram in which a fourth embodiment of the present invention is described.

### DETAILED DESCRIPTION OF THE INVENTION

Embodiments of an ion conducting actuator apparatus, and an optical diaphragm apparatus (diaphragm mechanism) which includes the ion conducting actuator apparatus according to the present invention will be described below in detail by referring to the accompanying diagrams. However, the present invention is not restricted by these embodiments.

### FIRST EMBODIMENT

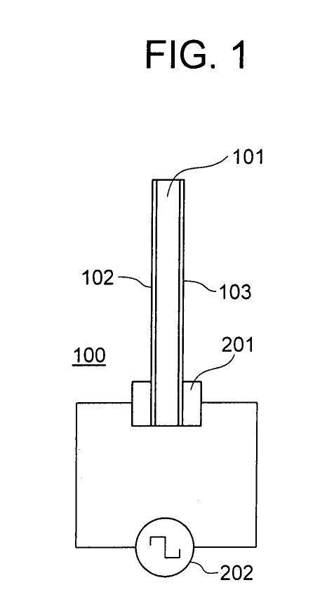

A first embodiment will be described by using FIG. 1 to FIG. 7. A driving mode of the ion conducting actuator apparatus (hereinafter, appropriately called as ‘ion conducting actuator’ as well) according to the present invention will be described by using FIG. 1.

FIG. 1 is a diagram in which, electrical connections of a drive voltage source 202 and an ion conducting actuator 100 are shown schematically. As shown in FIG. 1, the ion conducting actuator 100 includes a base material 101 made of an ion exchange resin, containing ion and/or polar molecules which are movable according to an electric field, and facing electrodes 102 and 103 which are formed on a surface of the base material 101 by an electroless plating method. Moreover, an output from a drive voltage source 202 is applied to the facing electrodes 102 and 103 via an electrode pad 201.

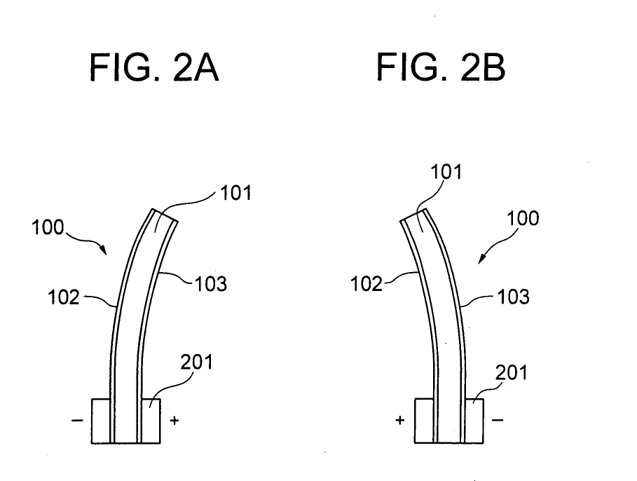

FIG. 2A and FIG. 2B are diagrams showing a deformed state when a negative voltage and a positive voltage are applied to the facing electrodes 102 and 103 respectively. As shown in FIG. 2A, in the diagram, when a negative voltage is applied to the facing electrode 102 which is formed on a left side of the ion conducting actuator 100, and a positive voltage is applied to the facing electrode 103 which is formed on a right side of the ion conducting actuator 100, due to an electric field generated by the voltage applied, positive ions and/or polar molecules in the base material 101 move toward a negative pole, and the negative pole side is swollen as compared to a positive pole side, and a front end of the base material 101 is deformed toward a right side in the diagram.

On the other hand, as shown in FIG. 2B, when a negative voltage is applied to the facing electrode 103 which is formed on the right side of the ion conducting actuator 100, and a positive voltage is applied to the facing electrode 102 which is formed on the left side of the ion conducting actuator 100, due to the electric field generated by the voltage applied, positive ions and/or polar molecules in the base material move toward the negative pole, and the front end of the base material 101 is deformed toward a left side in the diagram. In this manner, the ion conducting actuator 100 is an actuator in which a deformation of the base material 101 caused due to the voltage applied is used.

Moreover, the positive voltage and the negative voltage which are applied to the ion conducting actuator 100 are parameters which determine a direction of deformation, and in the description, although only cases in which the positive voltage or the negative voltage is applied are mentioned, a similar effect is achieved even in a case in which the voltage is applied with a polarity which is reverse of the polarity described here.

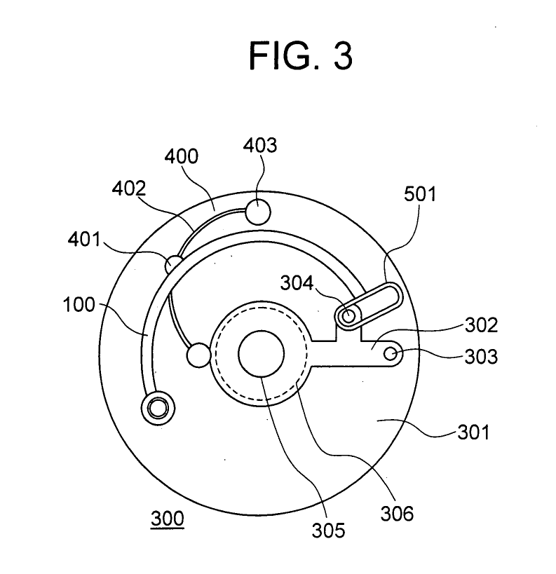

Next, a driving mode of the ion conducting actuator apparatus 100 according to the present invention will be described below by using FIG. 3. In the first embodiment, an example in which the ion conducting actuator 100 is applied to an inserting type binary diaphragm apparatus having two states namely an open state and a partially open state will be described.

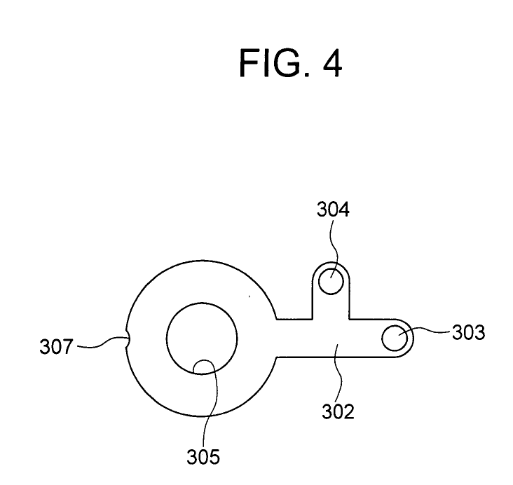

FIG. 3 shows a structure of a diaphragm apparatus which includes an ion conducting actuator and a diaphragm mechanism, and FIG. 4 is a diagram in which a diaphragm blade is shown in an enlarged form.

A diaphragm mechanism 300 shown in FIG. 3 includes a substrate 301 in which a first aperture 306 is formed, a diaphragm blade 302 in which a second aperture 305, a rotating shaft 303, a driving shaft 304, and a notch 307 are formed, and a latching mechanism 400 which includes a fixing section 401, an elastic section 402, and a fitting section 403.

Moreover, the ion conducting actuator 100 is formed to be circular arc shaped, and one end thereof is fixed to the substrate 301, and the other end is joined to a connecting mechanism 501 having a hollow elliptical shape.

In the first embodiment, the diaphragm blade 302 and the connecting mechanism 501 are driven sections, the connecting mechanism 501 and the driving shaft 304 are connecting members, and the latching mechanism 400 and the notch 307 are holding means.

An operation of the diaphragm mechanism 300 will be described below.

The diaphragm blade 303 perform a rotation operation with a rotating shaft 303 as a center of rotation, by making a driving force to act on the driving shaft 304. In a state shown in FIG. 3, since the diaphragm blade 302 is in a state of covering the first aperture 306 formed in the substrate 301, the final aperture diameter is a diameter of the second aperture 305 formed in the diaphragm blade 302, and this state is a state in which the diaphragm is partially opened.

On the other hand, as it will be described later, when a driving force is made to act on the driving shaft 304, and the diaphragm blade 302 is rotated (turned) to a position of being retracted from the first aperture 306 formed in the substrate 301, the final aperture diameter is (a diameter of) the first aperture 306 formed in the substrate 301, and this state is a state in which the diaphragm is opened.

Moreover, the latching mechanism 400 is capable of maintaining a state of the diaphragm blade 302 by the fixing section 401 being joined to the substrate 301, and the fitting section 403 and the notch 307 of the diaphragm blade 302 being fitted. Furthermore, since the fixing section 401 and the fitting section 403 are connected by the elastic section 402, the fitting of the fitting portion 403 and the notch 307 of the diaphragm blade 302 is disengaged by imparting a driving force of a certain level, and it is possible to drive the diaphragm blade 302.

Moreover, by applying a drive voltage as described earlier, the ion conducting actuator 100 is deformed such that a chord length of the circular arc is increased or decreased.

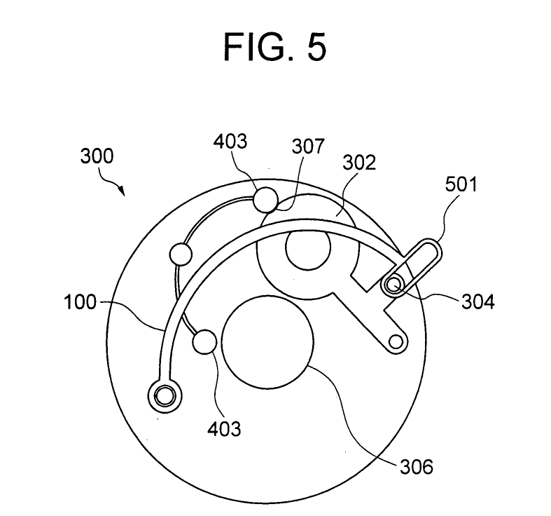

As shown in FIG. 3 and FIG. 5, since the connecting mechanism 501 is joined to a front end of the ion conducting actuator 100, and is connected to the driving shaft 304, it is possible to drive the diaphragm blade 302 by deforming the ion conducting actuator 100.

Details of a driving mode of the diaphragm apparatus according to the present invention will be described below by using FIG. 3, and FIG. 5 to FIG. 7. FIG. 3 is a partially open state described earlier, and this is a first effective state.

This first effective state is a state in which it is optically possible to take a picture. Moreover, in the first effective state, the voltage is not applied to the ion conducting actuator 100, and is an original shape (neutral shape) of the base material. Furthermore, in the first effective state, in the diagram, it is desirable that it is a state in which the driving shaft 304 is disposed and no driving force whatsoever acts.

FIG. 5 is a state in which, the voltage is applied to the ion conducting actuator 100, and deformed such that the chord length is extended. By applying the voltage to the ion conducting actuator 100 and extending the chord length, the connecting mechanism 501 acts on the driving shaft 304, and the diaphragm blade 302 is rotated to a position of being retracted from the first aperture 306 formed in the substrate 301. This state is let to be a first transition state. The actual first transition state is a period starting from a time when in the first effective state, the voltage is applied to the ion conducting actuator 100 and the diaphragm blade 302 is started to be rotated, till the diaphragm blade 302 is rotated up to a position of being retracted from the first aperture 306 formed in the substrate 301, and the state in FIG. 5 shows a final mode of the first transition state. This first transition state is a state in which it is not optically possible to take a picture.

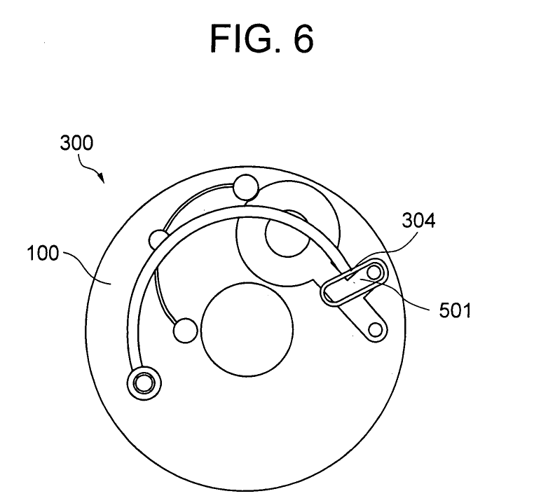

FIG. 6 is a state of being open, and is let to be the second effective state. This second effective state is a state in which it is optically possible to take a picture. Moreover, in the second effective state, the voltage is not applied to the ion conducting actuator 100, and is an original shape (neutral shape) of the base material 101. Furthermore, in the second effective state, in the diagram, it is desirable that it is a state in which the driving shaft 304 is disposed and no driving force whatsoever acts.

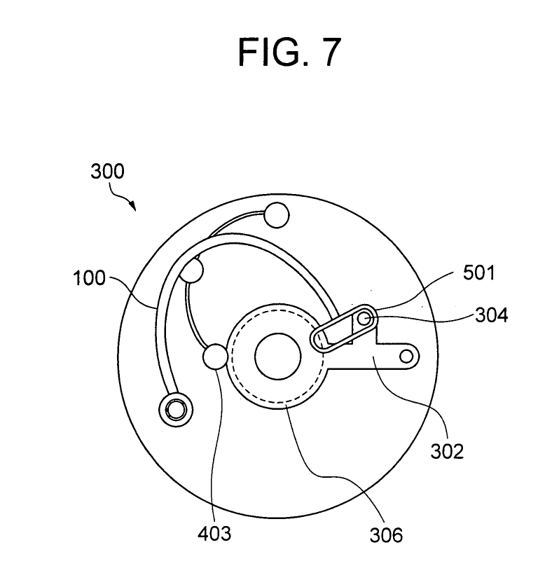

FIG. 7 is a state in which, the voltage is applied to the ion conducting actuator 100, and deformed such that the chord length is shortened. By applying the voltage to the ion conducting actuator 100 and shortening the chord length, the connecting mechanism 501 acts on the driving shaft 304, and the diaphragm blade 302 is rotated to a position of covering the first aperture 306 formed in the substrate 301. This state is let to be the second transition state. The actual second transition state is a period starting from a time when in the second effective state, the voltage is applied to the ion conducting actuator 100 and the diaphragm blade 302 is started to be rotated, till the diaphragm blade 302 is rotated up to a position of hiding the first aperture 306 formed in the substrate 301, and the state in FIG. 7 shows a final mode of the second transition state. This second transition state is a state in which it is not optically possible to take a picture.

Next, each component of the ion conducting actuator apparatus according to the present invention will be described below. First of all, the circular arc shape of the ion conducting actuator 100 will be described below.

AS shown in FIG. 3 and FIG. 6, regarding a neutral shape and a position of fixing to substrate 301 of the ion conducting actuator 100, in the first effective state and the second effective state, it is desirable that a position of the driving shaft 304 in each effective state is a symmetric position with respect to a central position of the connecting mechanism 501, when a longitudinal direction of the hollow elliptical shaped connecting mechanism 501 is considered to be an axis. By setting the circular arc shape and an installing position of the ion conducting actuator 100 in this manner, it is possible to make a response time same when the diaphragm blade 302 is partially open and open.

Next, a shape of the connecting mechanism 501 will be described below. The connecting mechanism has a hollow elliptical shape, and makes a contact with the driving shaft 304 at an inner wall, and transmits to the diaphragm blade 302, a driving force along with the deformation of the ion conducting actuator 100. It is desirable to set a length of this ellipse in a longitudinal direction to be same as a shift of the driving shaft 304 (in a precise sense, a length obtained by adding a diameter of the shaft to an amount of displacement of the driving shaft 304). By setting the shape of the connecting mechanism 501 in this manner, in the effective state, the driving shaft 304 makes a contact with the inner wall of the connecting mechanism 501, but is in a state of no force acting.

In this manner, by allowing the driving shaft 304 to make a contact with the inner wall of the connecting mechanism 501, since it is possible to eliminate wasting time after the ion conducting actuator 100 is deformed, till the connecting mechanism 501 makes a contact with the driving shaft 304, it is possible to shorten a response time.

Moreover, by making the driving section 304 not to exert a force on the connecting mechanism 501, it is possible to set low, a force of constraint on the diaphragm blade 302 by the latching mechanism 400, without an unnecessary force acting on the diaphragm blade 302. Therefore, it is possible to lower the driving force of the ion conducting actuator 100, and a time required for releasing the diaphragm blade 302 from the latching mechanism 400 is shortened, and it is possible to shorten a time which is necessary for the transition state.

Next, the latching mechanism 400 will be described below. In the first embodiment, the description has been made by using a mechanism which constrains the diaphragm blade 302 by an elastic force, as the latching mechanism 400. However, various other modes such as a method of fixing the diaphragm blade 302 by using an electromagnetic force, and a method of fixing the diaphragm blade 302 by setting suitably a friction of the rotating shaft 303 can be taken into consideration.

As it has been mentioned earlier, by repeating the first effective state, the first transition state, the second effective state, and the second transition state, an operation of opening and partially opening the diaphragm apparatus is possible. Moreover, from a point of view of time, normally, the first effective state and the second effective state take up most of the time, and the first transition state and the second transition state are for very short time. Therefore, the time for which the voltage is applied to the ion conducting actuator 100 becomes very short, and a cause for an occurrence of degradation of characteristics is reduced, and it is possible to improve durability.

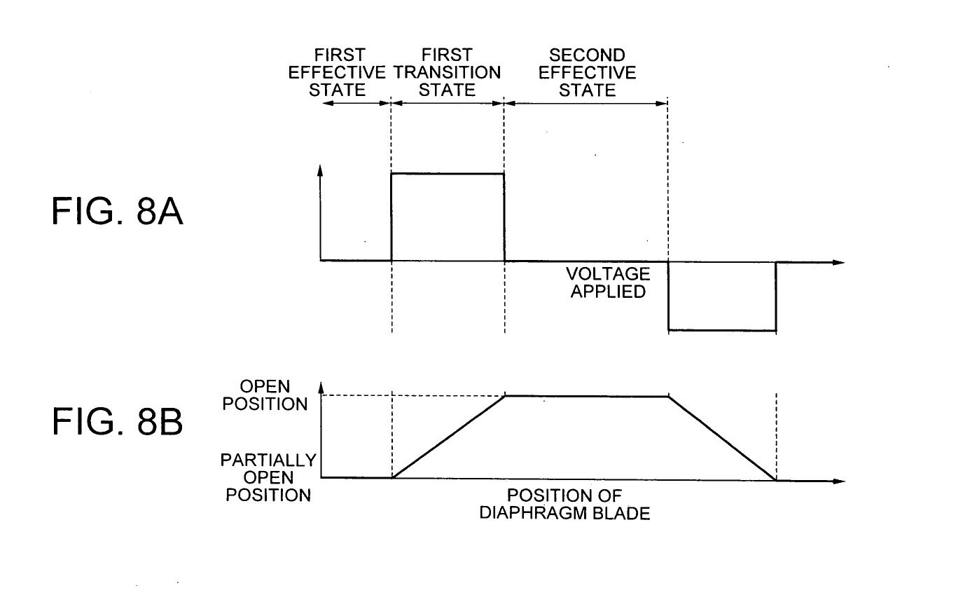

Next, a relationship of the position of the diaphragm blade, the effective state, the transition state, and the voltage applied to the ion conducting actuator 100 will be described below by using FIG. 8 to FIG. 10.

FIG. 8A and FIG. 8B is the most basic usage pattern as mentioned above. As shown in FIG. 8A and FIG. 8B, when the diaphragm blade 302 is at the partially open position, and no voltage is applied to the ion conducting actuator 100, the first effective state is assumed. Next, during a time when the diaphragm blade 302 is being shifted from the partially open position to the open position by applying the voltage to the ion conducting actuator 100, the first transition state is assumed. Next, when the diaphragm blade 302 reaches the open position, and no voltage is applied to the ion conducting actuator 100, the second effective state is assumed.

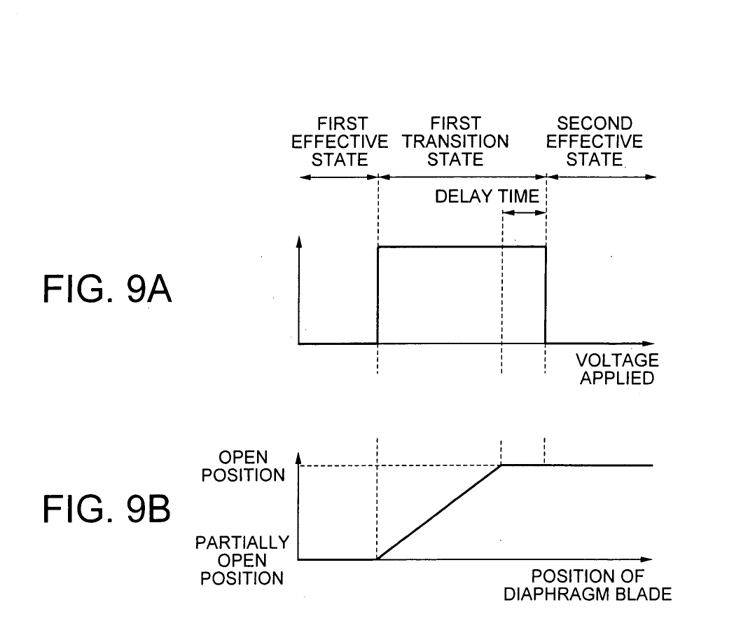

FIG. 9A and FIG. 9B is a usage pattern when a delay time is provided for settling that state assuredly, after the diaphragm blade 302 has assumed the partially open position or the open position.

As shown in FIG. 9A and FIG. 9B, during the time when the diaphragm blade 302 is at the partially open position, and no voltage is applied to the ion conducting actuator 100, the first effective state is assumed. Next, during a time when the diaphragm blade 302 is being shifted from the partially open position to the open position by applying the voltage to the ion conducting actuator 100, and further the delay time which is provided for settling that position, the first transition state is assumed. Next, when the diaphragm blade 302 is at the open position, and no voltage is applied to the ion conducting actuator 100, the second effective state is assumed.

A reason for the necessity of the delay time will be described below. Some sort of a detector is necessary for checking that the diaphragm blade 302 is assuredly at the partially open position or the open position, and is constrained by the latching mechanism 400. For providing such a detector, a suitable area for installation, a supply from a driving power supply, and a processing of a detection signal are necessary. Therefore, when a state of the diaphragm blade 302 is to be controlled by controlling time, without using a detector, it is desirable to provide such delay time.

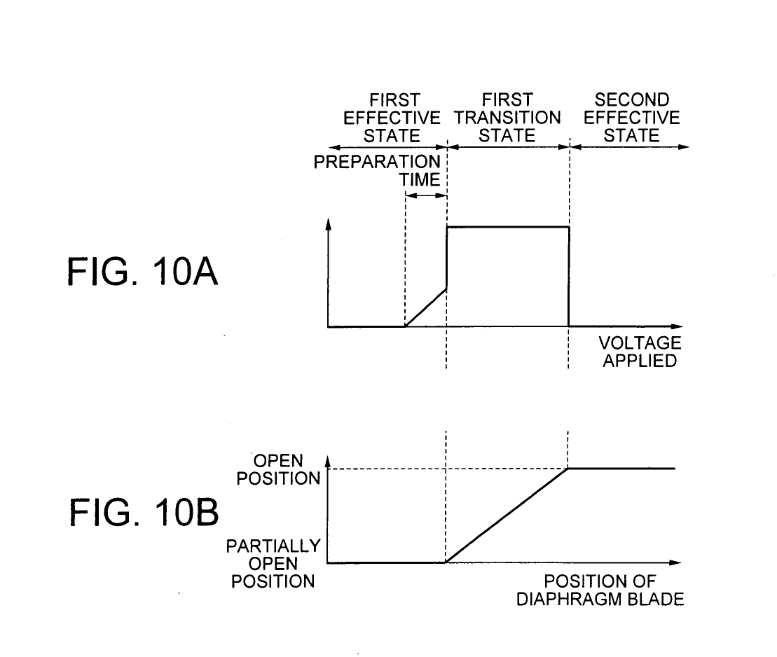

FIG. 10A and FIG. 10B is usage pattern when a preparation time is provided, for applying a preparation voltage to the ion conducting actuator 100 in advance, for eliminating a delay during a time while being released from the latching mechanism 400, at the time of driving the diaphragm blade 302.

As shown in FIG. 10A and FIG. 10B, during the time when the diaphragm blade 302 is at the partially open position, and no voltage is applied to the ion conducting actuator 100, and during a time from applying the preparation voltage to the ion conducting actuator 100 till the diaphragm blade 302 is released from the latching mechanism 400, the first effective state is assumed. Here, the ‘preparation voltage’ is a voltage necessary for the driven section to start displacement. Next, during the time when the diaphragm blade 302 is being shifted from the partially open position to the open position by applying the voltage to the ion conducting actuator 100, the first transition state is assumed. Next, when the diaphragm blade 302 is at the open position, and no voltage is applied to the ion conducting actuator 100, the second effective state is assumed.

A reason for the necessity of the preparation time will be described below. A generative force of the ion conducting actuator 100 has a characteristic of rising gradually after the voltage is applied. Therefore, certain time is required for the driving force of the ion conducting actuator 100 to reach a force which releases the diaphragm blade 302 from the latching mechanism 400, and this time is a delay time. Consequently, by generating in advance, a force in the ion conducting actuator 100, by which the diaphragm blade 302 is released from the latching mechanism 400, it is possible to eliminate the delay time. Such a method is effective when the first state and the second state are repeated periodically, and when a time of making a transition from the first state to the second state is known in advance.

The abovementioned description is made by taking an example of an inserting type binary diaphragm apparatus having two states namely the open state and the partially open state, as an ion conducting actuator apparatus. However, it is also possible to use for various applications such as a focus lens having two states, one for a far point and one for a near point, and a switch having two states of ON and OFF.

### SECOND EMBODIMENT

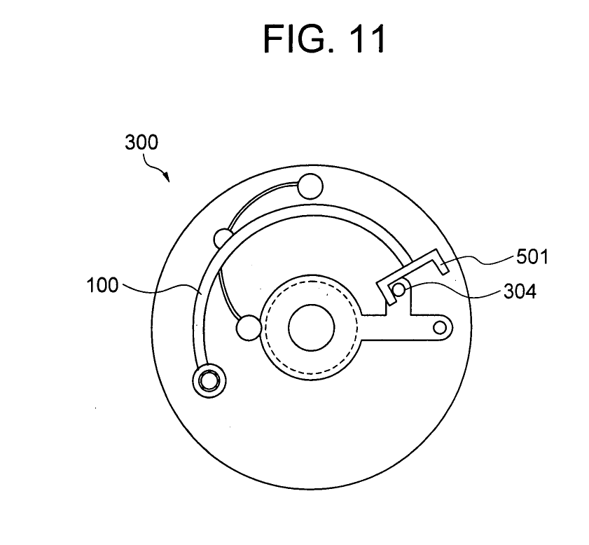

Next, a second embodiment of the present invention will be described by using FIG. 11. Same reference numerals are used for components which are same as in the first embodiment, and the description to be repeated is omitted. The second embodiment differs from the first embodiment at a point that the connecting mechanism which is jointed to the front end of the ion conducting actuator 100 has such as a U-shape as shown in FIG. 11. Similarly as in the description in the first embodiment, it is desirable to set a length of the connecting mechanism in a longitudinal direction of the English alphabet C to be same as the shift of the driving shaft 304.

### THIRD EMBODIMENT

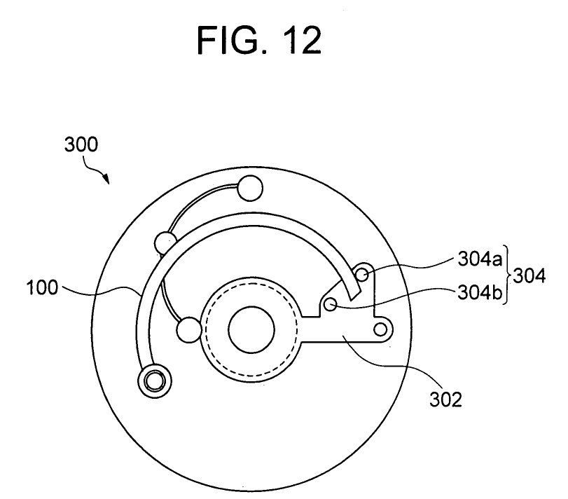

Next, a third embodiment will be described by using FIG. 12. Same reference numerals are used for components which are same as in the first embodiment, and the description to be repeated is omitted. The third embodiment differs from the first embodiment and the second embodiment at points that two driving shafts 304 are provided to the diaphragm blade 302, and the front end of the ion conducting actuator 100 is clamped between these two driving shafts 304a and 304b, as shown in FIG. 12.

In the third embodiment, the connecting mechanism 501 is not provided separately. However, it is possible to have an effect similar to the effect of the connecting mechanism 501 described earlier, by providing the driving shafts 304 at two locations as described earlier, and disposing the front end of the ion conducting actuator 100 between the two driving shafts 304.

### FOURTH EMBODIMENT

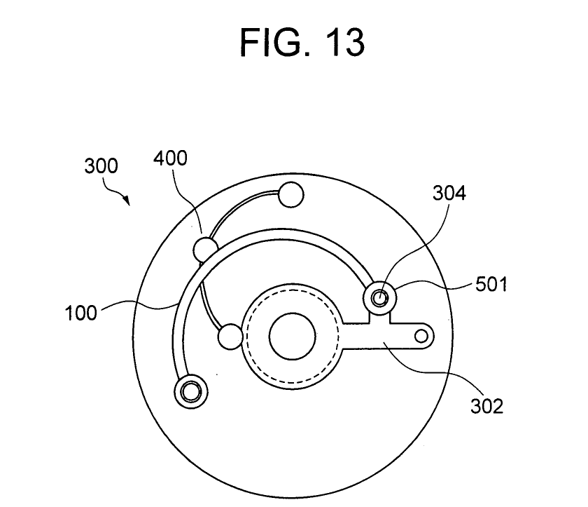

Next a fourth embodiment of the present invention will be described by using FIG. 13. Same reference numerals are used for components which are same as in the first embodiment, and the description to be repeated is omitted. The fourth embodiment differs from the first embodiment, the second embodiment, and the third embodiment at a point that by letting the connecting mechanism 501 which is joined to the front end of the ion conducting actuator 100, to be hollow circular shaped as shown in FIG. 13, there is almost no clearance left for the connecting mechanism 501 with respect to a driving direction of the driving shaft 304.

In the fourth embodiment, there is no change from the embodiments described above, at a point that when the diaphragm blade 302 is between the first effective state and the second effective state, the voltage is not applied to the ion conducting actuator 100.

By adopting such structure, since the diaphragm blade 302 is maintained to be in that state by the latching mechanism 400, the ion conducting actuator 100 is also maintained in that shape. Moreover, when the state of the diaphragm blade 302 is to be made to undergo a transition, it is possible to drive the diaphragm mechanism 300 by imparting a driving force by the ion conducting actuator 100, which is not weaker than the force by which the diaphragm blade 302 is released from the latching mechanism 400.

In this manner, the fourth embodiment is operative when the driving force of the ion conducting actuator 100 is comparatively stronger than a holding force of the latching mechanism 400, and a force of deforming the shape of the ion conducting actuator 100 by an external force is comparatively weaker than the holding force of the latching mechanism 400. By adopting the fourth embodiment, it is possible to reduce an occupied area of the connecting mechanism 501 resulted from the driving of the diaphragm apparatus, and to make the diaphragm apparatus small-size.

Moreover, it is possible to halve substantially, the amount of deformation of the ion conducting actuator 100, which is necessary for driving the diaphragm blade 302, as compared to the deformation in the embodiments described above.

In the fourth embodiment, the description has been made by using a hollow circular shape as the connecting mechanism 501. However, as a similar driving mode, it is possible to adopt another mode such as a U-shape shown in the second embodiment, and providing two driving shafts 304 shown in the third embodiment.

As it has been described above, in the present invention, the voltage is applied to the ion conducting actuator only when it is necessary. Therefore, it is possible to prevent a state in which the voltage is applied continuously to the ion conducting actuator when it is not necessary. As a result of this, it is possible to improve durability of the ion conducting actuator. Moreover, a response of the ion conducting actuator may be deteriorated when the voltage is applied continuously. In the present invention, the voltage is applied to the ion conducting actuator only when it is necessary. Therefore, it is possible to improve the response of the ion conducting actuator.

As it has been described above, the ion conducting actuator apparatus according to the present invention is useful as an ion conducting actuator apparatus in which, the durability and the response etc. are taken in to consideration, and a more suitable operation can be realized, and is appropriate for a use as an actuator of an optical diaphragm apparatus.

The present invention can provide an ion conducting actuator apparatus in which, the durability and the response etc. are taken into consideration, and a more suitable operation can be realized. Moreover, it is possible to provide an optical diaphragm apparatus in which the ion conducting actuator apparatus is used.

What is claimed is:

1. An ion conducting actuator apparatus comprising:
an ion conducting actuator which includes a base material made of an ion conducting high-polymer material, and facing electrodes which are formed on a surface of the base material; and
a driven section which assumes a first effective state and a second effective state according to a deformation of the ion conducting actuator, when a voltage is applied to the ion conducting actuator, wherein
during a transition period in which the driven section undergoes a transition between the first effective state and the second effective state, a drive voltage which is necessary for displacing the driven section is applied.

2. The ion conducting actuator apparatus according to claim 1, wherein
the voltage is not applied to the ion conducting actuator during a period other than the transition period.

3. The ion conducting actuator apparatus according to claim 2, wherein
the driven section includes a connecting member which connects the driven section and the ion conducting actuator, and the driven section undergoes a transition mutually between the first effective state and the second effective state via the connecting member.

4. The ion conducting actuator apparatus according to claim 3, wherein
the connecting member is joined to the ion conducting actuator, and includes a first contact section and a second contact section, and
due to a contact section provided on the driven section making a contact with the first contact section, when the driven section undergoes a transition to the first effective state, and
due to the contact section and the second contact section making a contact, when the driven section undergoes a transition to the second effective state,
the driven section is made to undergo a transition mutually to the first effective state and the second effective state.

5. The ion conducting actuator apparatus according to claim 4, further comprising:
a holding means which maintains a state of the driven section, wherein
when the driven section has undergone a transition to the first effective state or the second effective state according to the deformation of the ion conducting actuator, the holding means maintains the state of the driven section.

6. The ion conducting actuator apparatus according to claim 3, wherein
the connecting member is joined to the driven section, and includes a first contact section and a second contact section, and
also includes a contact section which is joined to or provided to the ion conducting actuator, and
due to the contact section and the first contact section making a contact, when the driven section undergoes a transition to the first effective state, and
due to the contact section and the second contact section making a contact, when the driven section undergoes a transition to the second effective state,
the driven section is made to undergo a transition mutually to the first effective state and the second effective state.

7. The ion conducting actuator apparatus according to claim 6, further comprising:
a holding means which maintains a state of the driven section, wherein
when the driven section has undergone a transition to the first effective state or the second effective state according to the deformation of the ion conducting actuator, the holding means maintains the state of the driven section.

8. The ion conducting actuator apparatus according to claim 1, wherein
a preparation voltage which is necessary for the driven section to start displacement is applied to the ion conducting actuator during a period other than the transition period.

9. The ion conducting actuator apparatus according to claim 8, wherein
the driven section includes a connecting member which connects the driven section and the ion conducting actuator, and the driven section undergoes a transition mutually to the first effective state and the second effective state via the connecting member.

10. The ion conducting actuator apparatus according to claim 9, wherein
the connecting member is joined to the ion conducting actuator, and includes a first contact section and a second contact section, and
due to a contact section provided on the driven section, making a contact with the first contact section, when the driven section undergoes a transition to the first effective state, and
due to the contact section and the second contact section making a contact, when the driven section undergoes a transition to the second effective state,
the driven section is made to undergo a transition mutually to the first effective state and the second effective state.

11. The ion conducting actuator apparatus according to claim 10, further comprising:
a holding means which maintains a state of the driven section, wherein
when the driven section has undergone a transition to the first effective state or the second effective state according to the deformation of the ion conducting actuator, the holding means maintains the state of the driven section.

12. The ion conducting actuator apparatus according to claim 9, wherein
the connecting member is joined to the driven section, and
includes a first contact section and a second contact section, and
also includes a contact section which is joined to or provided on the ion conducting actuator, and
due to the contact section and the first contact section making a contact, when the driven section undergoes a transition to the first effective state, and
due to the contact section and the second contact section making a contact when the driven section undergoes a transition to the second effective state,
the driven section is made to undergo a transition mutually to the first effective state and the second effective state.

13. The ion conducting actuator apparatus according to claim 12, further comprising:
a holding means which maintains a state of the driven section, wherein
when the driven section has undergone a transition to the first effective state or the second effective state according to the deformation of the ion conducting actuator, the holding means maintains the state of the driven section.

14. The ion conducting actuator apparatus according to claim 1, wherein
during the transition period, after the ion conducting actuator is deformed to a predetermined shape, the voltage is applied continuously till the second effective state.

15. The ion conducting actuator apparatus according to claim 14, wherein
the driven section includes a connecting member which connects the driven section and the ion conducting actuator, and the driven section undergoes a transition mutually to the first effective state and the second effective state via the connecting member.

16. The ion conducting actuator apparatus according to claim 15, wherein
the connecting member is joined to the ion conducting actuator, and includes a first contact section and a second contact section, and
due to a contact section provided on the driven section, making a contact with the first contact section, when the driven section undergoes a transition to the first effective state, and
due to the contact section and the second contact section making a contact when the driven section undergoes a transition to the second effective state,
the driven section is made to undergo a transition mutually to the first effective state and the second effective state.

17. The ion conducting actuator apparatus according to claim 16, further comprising:
a holding means which maintains a state of the driven section, wherein
when the driven section has undergone a transition to the first effective state or the second effective state according to the deformation of the ion conducting actuator, the holding means maintains the state of the driven section.

18. The ion conducting actuator apparatus according to claim 15, wherein
the connecting member is joined to the driven section, and
includes a first contact section and a second contact section, and
also includes a contact section which is joined to or provided on the ion conducting actuator, and
due to the contact section and the first contact section making a contact, when the driven section undergoes a transition to the first effective state, and
due to the contact second and the second contact section making a contact, when the driven section undergoes a transition to the second effective state,
the driven section is made to undergo a transition mutually to the first effective state and the second effective state.

19. The ion conducting actuator apparatus according to claim 18, further comprising:
a holding means which maintains a state of the driven section, wherein
when the driven section has undergone a transition to the first effective state or the second effective state according to the deformation of the ion conducting actuator, the holding means maintains the state of the driven section.

20. The ion conducting actuator apparatus according to claim 1, wherein
the driven section includes a connecting member which connects the driven section and the ion conducting actuator, and the driven section undergoes a transition mutually to the first effective state and the second effective state via the connecting member.

21. The ion conducting actuator apparatus according to claim 20, wherein
the connecting member is joined to the ion conducting actuator, and includes a first contact section and a second contact section, and
due to a contact section provided on the driven section, making a contact with the first contact section, when the driven section undergoes a transition to the first effective state, and
due to the contact section and the second contact section making a contact, when the driven section undergoes a transition to the second effective state,
the driven section is made to undergo a transition mutually to the first effective state and the second effective state.

22. The ion conducting actuator apparatus according to claim 21, further comprising:
a holding means which maintains a state of the driven section, wherein
when the driven section has undergone a transition to the first effective state or the second effective state according to the deformation of the ion conducting actuator, the holding means maintains the state of the driven section.

23. The ion conducting actuator apparatus according to claim 20, wherein
the connecting member is joined to the driven section, and
includes a first contact section and a second contact section, and
also includes a contact section which is joined to or provided on the ion conducting actuator, and
due to the contact section and the first contact section making a contact, when the driven section undergoes a transition to the first effective state, and
due to the contact section and the second contact section making a contact, when the driven section undergoes a transition to the second effective state,
the driven section is made to undergo a transition mutually to the first effective state and the second effective state.

24. The ion conducting actuator apparatus according to claim 23, further comprising:
a holding means which maintains a state of the driven section, wherein
when the driven section has undergone a transition to the first effective state or the second effective state according to the deformation of the ion conducting actuator, the holding means maintains the state of the driven section.

25. An optical diaphragm apparatus comprising:
an ion conducting actuator provided on a substrate which includes a substrate having an aperture, a blade having an aperture smaller than the aperture formed in the substrate, a base material which is formed of a ion conducting high-polymer material, and facing electrodes which are formed on a surface of the base material, wherein
a voltage is applied to the ion conducting actuator, and a blade having an aperture is driven according to a deformation of the ion conducting actuator, and made to undergo a transition between a first effective state of overlapping with the aperture formed in the substrate, and a second effective state of being retracted from the aperture formed in the substrate, thereby changing an aperture diameter, and
during a transition period in which a transition between the first effective state and the second effective state occurs, a drive voltage which is necessary for driving the ion conducting actuator is applied.

26. The optical diaphragm apparatus according to claim 25, further comprising:
a holding means which maintains a state of the blade having the aperture, wherein
when the blade having the aperture has undergone transition to the first effective state or the second effective state according to the deformation of the ion conducting actuator, the holding means maintains the state of the driven section.
